(19) United States
(12) Patent Application Publication
(10) Pub. No.: US 2026/0110754 A1
(43) Pub. Date: Apr. 23, 2026

(54) METHOD AND SYSTEM FOR PREDICTING HEALTH STATE OF BATTERY ENERGY STORAGE SYSTEM WITH COLD START DEPLOYMENT CAPABILITY

(71) Applicants: LITE-ON TECHNOLOGY CORPORATION, TAIPEI CITY (TW); LITE-ON SINGAPORE PTE. LTD., SINGAPORE (SG)

(72) Inventors: JINLONG WANG, SINGAPORE (SG); JING YANG, SINGAPORE (SG); CHENG-MING CHIEN, TAIPEI CITY (TW); YI CHIEH HUANG, TAIPEI CITY (TW)

(21) Appl. No.: 19/183,587

(22) Filed: Apr. 18, 2025

Related U.S. Application Data
(60) Provisional application No. 63/710,048, filed on Oct. 22, 2024.

(51) Int. Cl. G01R 31/392; G01R 31/367; G01R 31/374; G01R 31/3842; H01M 10/42; H01M 10/44

(52) U.S. Cl. CPC G01R 31/392; G01R 31/367; G01R 31/374; G01R 31/3842; H01M 10/425; H01M 2010/4271; H01M 10/44

(57) ABSTRACT

An apparatus for predicting a battery health state value of a target battery module having one or more electrochemical battery cells is provided. The apparatus includes a processor and a memory. The memory has computer-executable instructions stored thereupon which, when executed by the processor, cause the apparatus to perform the following operations: obtain a machine-learning model, which has been trained with first data segments and first battery health state values corresponding to first data segments associated with a reference battery module; collect battery charging data of the target battery module over one or more charging cycles of the target battery module; extract a second data segment from the battery charging data; transform the second data segment to align with the first data segments; and input the transformed second data segment to the machine-learning model to predict a battery health state value of the target battery module.

### CROSS-REFERENCE TO RELATED APPLICATION(S)

This application claims the benefit of U.S. Provisional Application No. 63/710,048, filed Oct. 22, 2024, the entire disclosure of which is incorporated by reference herein.

### BACKGROUND

Conventional data-driven solutions for estimating battery health state primarily rely on the availability of sufficient representative labelled data to effectively train the model. These methods necessitate that the data samples encompass the entire lifecycle of the battery, including the new stage, middle life stage, and aged stage. These conventional methods characterize battery health solely based on the maximum capacity remaining ratio relative to the rated value. However, these conventional methods often overlook the random properties of onsite charging operation profiles, which can pose significant challenges during model deployment. This oversight can lead to inaccuracies in battery health estimation, as the variability in real-world operation conditions is not fully accounted for. Therefore, there is a need for more comprehensive methods that integrate these random operational factors to enhance the reliability and accuracy of battery health state estimation.

### SUMMARY OF THE DISCLOSURE

Thus, a computer system and an apparatus for predicting a health state of a battery energy storage system are provided to address the aforementioned problems, such as the randomness in onsite charging profiles and the lack of long-term operational data. Additionally, the computer system and apparatus offers a customized estimation of battery health values for data labeling.

In an aspect of the present disclosure, a computer system is provided, which includes a processor and a memory. The memory has computer-executable instructions stored thereupon which, when executed by the processor, cause the computer system to: collect a plurality of time series measurements, which includes voltage measurements and charge capacity measurements, sampled from a reference battery module over a plurality of charging cycles; calculate a plurality of differential voltage (DV) values based on the voltage measurements and the charge capacity measurements corresponding to each of the plurality of charging cycles; identify a plurality of minimum DV values each corresponding to a respective charging cycle of the plurality of charging cycles; calculate a plurality of battery health state values corresponding to the plurality of charging cycles based on the plurality of minimum DV values; extract a segment pool, which includes a plurality of data segments, from the time series measurements over a plurality of constant current charging phases corresponding to the plurality of charging cycles; and train a machine-learning model with the segment pool and the corresponding ones of the plurality of battery health state values.

In another aspect of the present disclosure, an apparatus for predicting a battery health state value of a target battery module is provided. The target battery module includes one or more electrochemical battery cells. The apparatus includes a processor and a memory. The memory has computer-executable instructions stored thereupon which, when executed by the processor, cause the apparatus to: obtain a machine-learning model, which has been trained with a plurality of first data segments and a plurality of first battery health state values corresponding to the plurality of first data segments associated with a reference battery module; collect battery charging data of the target battery module over one or more charging cycles of the target battery module; extract a second data segment from the battery charging data; and transform the second data segment to align with the plurality of first data segments; and input the transformed second data segment to the machine-learning model to predict a battery health state value of the target battery module.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of a battery energy storage system in accordance with some embodiments of the present disclosure.

FIG. 2 is a block diagram of a computing device in accordance with some embodiments of the present disclosure.

FIG. 3A is a diagram of a training procedure and an inference procedure of a machine-learning model of a battery energy storage device in accordance with some embodiments of the present disclosure.

FIG. 3B is a diagram of the training procedure of the machine-learning model in FIG. 3A.

FIG. 3C is a diagram of the inference procedure of the machine-learning model in FIG. 3A.

FIG. 4 is a flowchart of operations in block 306 in accordance with the embodiment of FIG. 3A.

FIG. 5 is a flowchart of operations in block 312 in accordance with the embodiment of FIG. 3A.

FIG. 6 is a flowchart of operations in block 322 in accordance with the embodiment of FIG. 3A.

FIG. 7 is a flowchart of operations in block 324 in accordance with the embodiment of FIG. 3A.

FIG. 8 is a flowchart of operations in block 310 in accordance with the embodiment of FIG. 3A.

FIG. 9 is a diagram illustrating the relationship between voltage corresponding to the minimum DV value and the cycle index in accordance with some embodiments of the present disclosure.

FIG. 10A is a diagram illustrating a short-term battery charging-discharging profile in accordance with some embodiments of the present disclosure.

FIG. 10B is a diagram illustrating a long-term battery charging-discharging profile in accordance with some embodiments of the present disclosure.

FIG. 10C is a diagram illustrating a density distribution function with respect to state-of-charge (SoC) values in accordance with some embodiments of the present disclosure.

FIG. 10D is a diagram illustrating a relative percentage function with respect to state-of-charge (SoC) values in accordance with some embodiments of the present disclosure.

FIG. 11 is a diagram illustrating a battery charging profile, variations of the battery health state values, and a charging data extraction time window in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

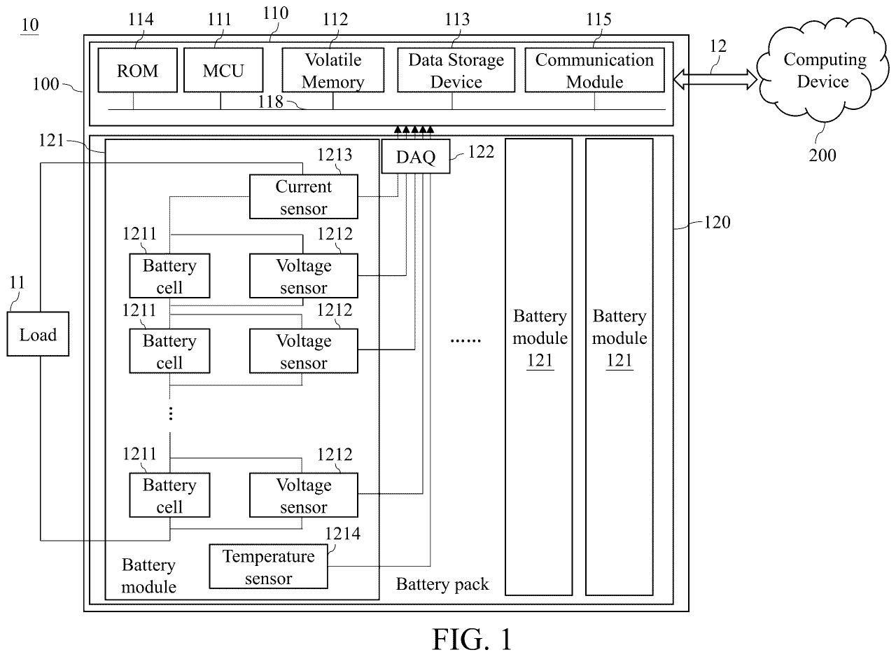

FIG. 1 is a block diagram of a battery energy storage system in accordance with some embodiments of the present disclosure.

In some embodiments, the battery energy storage system 10 includes a battery energy storage device 100 and a computing device 200. As depicted in FIG. 1, the battery energy storage device 100 may include a control device 110 and a battery pack 120. The battery pack 120 may include one or more battery modules 121 that are connected in series, in parallel, or a combination thereof, thereby providing energy storing and supplying energy to a load 11. The battery energy storage device 100 may be configured to collect battery information of each battery module therein, and sent the collected battery information to the computing device 200 through a communication link 12. The computing device 200 may be configured to predict a battery health state value of each battery cell 1211 within the battery energy storage device 100 along with a corresponding report using the collected battery information.

In some embodiments, each battery module 121 may include a plurality of battery cells 1211, a plurality of voltage sensors 1212, a current sensor 1213, and a temperature sensor 1214. The battery cells 1211 are connected in series to provide a voltage potential to the load 11 through the current sensor 1213, allowing the current sensor 1213 to detect the current flowing through the battery cells 1211 of the respective battery module 121. In some embodiments, the battery cells 1211 within each battery module 121 may be implemented using lithium-ion batteries such as lithium iron phosphate (LFP) batteries, lithium-nickel manganese cobalt oxide (NMC) batteries, or lithium cobalt oxide (LCO) batteries.

Additionally, the voltage sensors 1212 each is configured to detect the voltage potential across the respective battery cell 1211, as depicted in FIG. 1. The temperature sensor 1214 is configured to detect temperature information of the respective battery module 121. The current detected by the current sensor 1213, the voltages detected by the voltage sensors 1212, and the temperature information detected by the temperature sensor 1214 may be analog signals, which are sent to a data acquisition circuit (DAQ) 122. The data acquisition circuit 122 may include one or more multiplexers (not shown) configured to select the signals from one of the battery modules 121. Additionally, the data acquisition circuit 122 may further include analog-to-digital converters (ADC) that are configured to convert the analog signals from each battery module 121 to respective digital signals. Accordingly, the control device 110 can monitor the charging status of each battery module 121 using respective converted digital signals, including the current flowing through the battery cells 1211, the voltage across each battery cell 1211, and temperature information of each battery module 121.

In some embodiments, the control device 110 includes a microcontroller unit (MCU) 111, a volatile memory 112, a data storage device 113, a read-only memory (ROM) 114, and a communication module 115, which are electrically connected to each other through an internal bus 118. The volatile memory 112 can be either a static random access memory (SRAM) or a dynamic random access memory (DRAM), designed to temporarily store data during the operation of the firmware executed by the MCU 111. The data storage device 113 may be an internal storage option, such as a secure digital (SD) card, or an external storage option, like a hard disk drive or a solid-state disk, among, other, but the present disclosure is not limited thereto. The read-only memory 114 is configured to store the firmware (not shown) for the MCU 111, which may include functions such as monitoring charging and discharging status of the battery pack 120, transferring detected information from each battery module 121 to the computing device 200, receiving an estimated battery health state value of each battery cell 1211 along with a corresponding report thereof from the computing device 200, among other tasks.

In some embodiments, the battery health state value of a battery is an important metric that reflects the current condition of the battery pack in comparison to its ideal or original state. The battery health state value is generally expressed as a percentage. For example, when the capacity of a new battery is same as the nominal capacity as per the battery specification, it is said to be in optimal health (battery health state value=100%). As the battery continues to be used in a device, its health, in terms of capacity and other significant parameters, deteriorates until it reaches the end of life (battery health state value is approximately between 70% and 80%). As a result, such batteries are replaced from regular usage due to their unstable and unreliable performance. Generally, a battery's battery health state value will be 100% at the time of manufacture and will decrease over time and with use.

In some embodiments, the state of charge (SoC) of a battery refers to the current level of charge relative to its capacity, typically expressed as a percentage. It indicates how much energy is available for use before the battery needs recharging. A fully charged battery has an SoC of 100%, while a completely discharged battery has an SoC of 0%.

In some embodiments, the communication module 115 may include one or more wired communication modules and/or wireless communication modules to facilitate communication between the control device 110 and the computing device 200 via the communication link 12. For example, the wired communication modules may support, but are not limited to, wired communication protocols, such as controller area network (CAN), universal asynchronous receiver/transmitter (UART), serial peripheral interface (SPI), inter-integrated circuit (I2C), universal serial bus (USB), Ethernet, among others. The wireless communication modules may support, but are not limited to, wireless communication protocols, such as Wi-Fi, Bluetooth, and cellular protocols (e.g., 3G, 4G, 5G, 6G, and beyond).

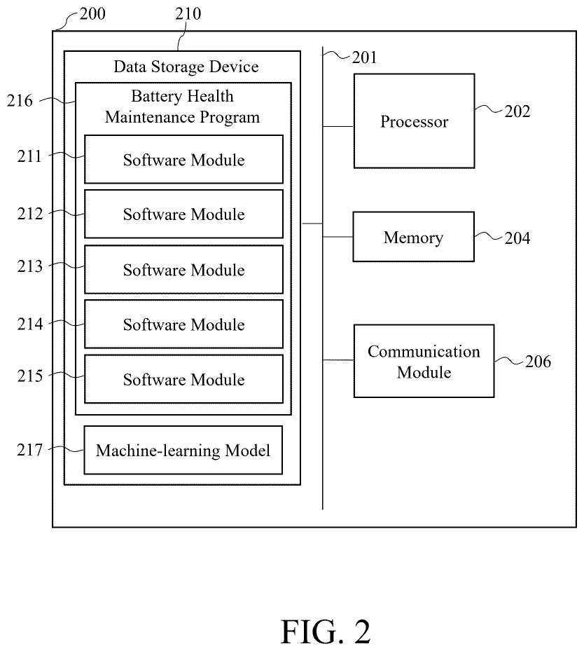

FIG. 2 is a block diagram of a computing device in accordance with some embodiments of the present disclosure.

In some embodiments, the computing device 200 may be an edge computing device or a cloud computing device. The computing device 200 may include at least a processor 202, a memory 204, a communication module 206, and a data storage device 210 that are electrically connected to each other via a bus 201. The processor 202 may be a central processing unit (CPU), a digital signal processor (DSP), a general-purpose processor, etc. The memory 204 may be a dynamic random access memory (DRAM) configured to serve as a system memory for storing intermedia data during operations of predicting the state of health of each battery cell 1211 within the battery energy storage device 100 using the collected battery information. The communication module 206 may be similar to the communication module 115 of the battery energy storage device 100. In some embodiments, the communication module 206 may include one or more wired communication modules and/or wireless communication modules to facilitate communication between the control device 110 and the computing device 200 via the communication link 12. For example, the wired communication modules may support, but are not limited to, wired communication protocols, such as controller area network (CAN), universal asynchronous receiver/transmitter (UART), serial peripheral interface (SPI), inter-integrated circuit (I2C), universal serial bus (USB), Ethernet, among others. The wireless communication modules may support, but are not limited to, wireless communication protocols, such as Wi-Fi, Bluetooth, and cellular protocols (e.g., 3G, 4G, 5G, 6G, and beyond).

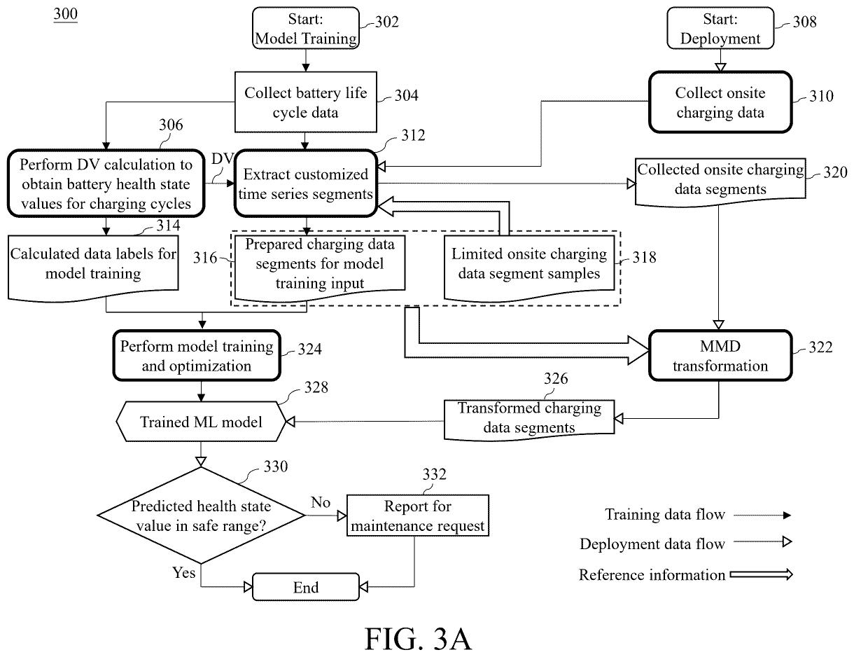

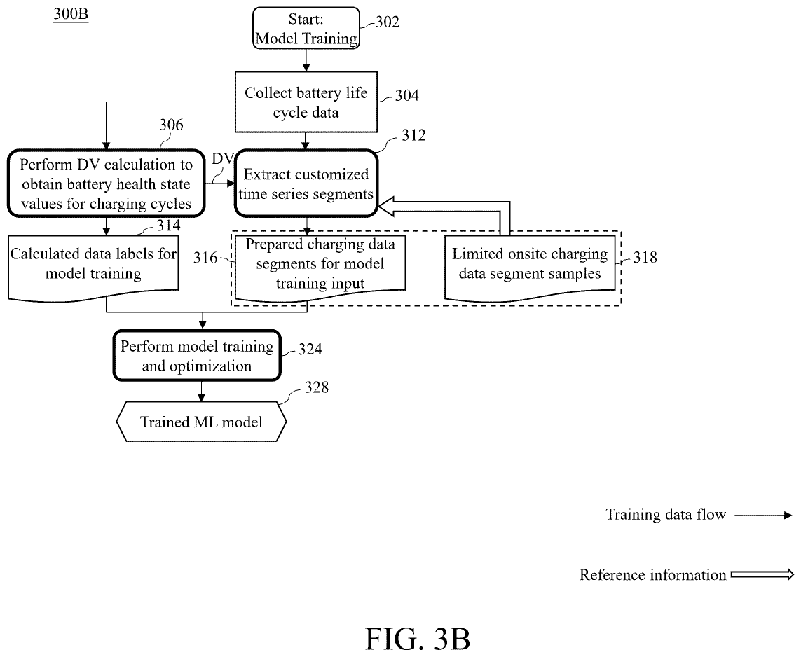

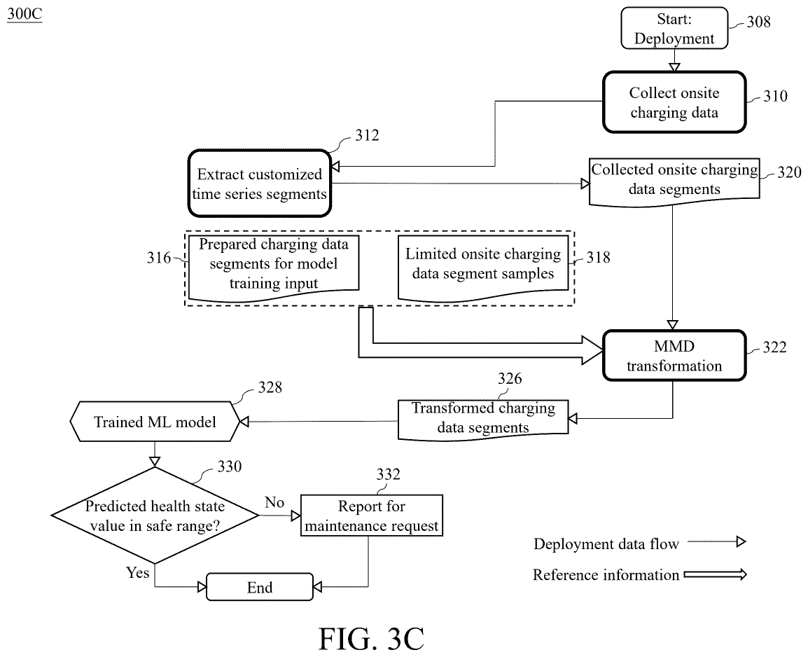

In some embodiments, the data storage device 210 may be a non-volatile memory, such as a hard-disk drive, a solid-state disk, etc., configured to store a battery health maintenance program 216 and a machine-learning model 217. The processor 202 may execute the battery health maintenance program 216 to training the machine-learning model 217 using collected input data from open sources and limited on-site deployment data. In some embodiments, the battery health maintenance program 216 may include software modules 211 to 215 configured to perform different operations during the training procedure of the machine-learning model 217. In some embodiments, the machine-learning model 217 may be a deep learning model, such as a long short-term memory (LSTM) model. For example, an LSTM model is a special kind of recurrent neural network (RNN), and it is capable of learning long-term dependencies and avoiding the long-term dependency problem. Since the battery life cycle test data includes a plurality long time segments (e.g., dozens of minutes), the machine-learning model 217, such as an LSTM model, can be used to predict the battery health state value of each battery cell 1211 within the battery energy storage device 100. In some embodiments, the machine-learning model 217 after training may be pre-stored in the data storage device 210 of the computing device 200. In some embodiments, the processor 202 of the computing device 200 may obtain the machine-learning model 217 from a cloud network after the battery energy storage device 100 is deployed. Further details of the battery health maintenance program 216 and software modules 211 to 215 will be described with reference to the embodiments of FIGS. 3A to 8.

FIG. 3A is a diagram of a training procedure and an inference procedure of a machine-learning model of a battery energy storage device in accordance with some embodiments of the present disclosure. FIG. 3B is a diagram of the training procedure of the machine-learning model in FIG. 3A. FIG. 3C is a diagram of the inference procedure of the machine-learning model in FIG. 3A. Please refer to FIGS. 1, 2, and 3A to 3C simultaneously.

In some embodiments, flow 300 in FIG. 3A includes a plurality of blocks 302 to 332 which may include a combination of steps and specific data relevant to various stages of the training procedure for the machine-learning model 217. Generally, battery operation data covering different stages (e.g., including the new stage, middle life stage, and aged stage) of the life cycle of each battery cell 1211 within the battery energy storage device 100 is needed for training a machine-learning model 217 to predict the battery health state value of each battery cell 1211 within the battery energy storage device 100. Nevertheless, the availability of such data poses a significant challenge for training the machine-learning model 217 of a newly developed battery energy storage device 100 due to the very limited amount of operational data available.

It should be noted that when deploying a machine-learning model to a newly developed battery energy storage device 100 using the open-source battery life cycle test data (e.g., abbreviated as “open-source battery data” hereinafter) as the training data, some gaps may exist. In some embodiments, the battery life cycle data may consist of long-term operation data (e.g., a lifelong data set) from other batteries, which may be from different manufacturers, of the same type as the battery cells 1211 (e.g., LFP batteries, NMC batteries, or LCO batteries). Firstly, the lithium-ion batteries used in the training and deployment stages may be not identical. For example, the characteristics of charging curves may differ across lithium-ion batteries from various manufacturers, products, and technologies over time. Secondly, the battery life cycle data from most open sources lack labels of battery health states, which are needed for training the machine-learning model 271. Thirdly, the onsite battery operation profile (e.g., deployment battery data) differs from most open-source battery data collected from controlled laboratory tests. The proposed training procedure of the machine-learning model 217 shown in FIG. 3A can bridge the aforementioned gaps between the battery life cycle test data from open sources and the deployment battery operation data. In some embodiments, both the open-source battery data and the deployment battery operation data correspond to the same type of batteries, including LPF batteries, NMC batteries, LCO batteries, and so forth.

In some embodiments, flow 300B and 300C in FIGS. 3B and 3C are portions of flow 300 in FIG. 3A. For clarity, the training procedure of the machine-learning model 217 may involve blocks 302, 304, 306, 312, 314, 316, 318, 324, and 328, as depicted by flow 300B in FIG. 3B. For clarity, the inference procedure of the machine-learning model 217 (or deployment data flow) may involve blocks 308, 310, 312, 316, 318, 320, 322, 326, 328, 330, and 332, as depicted by flow 300C in FIG. 3C.

In block 302, a model training procedure starts, and battery life cycle test data is collected (block 304). In some embodiments, the battery life cycle test data in block 302 may be open-source battery data of lithium-ion batteries, which is of the same type as each battery cell 1211, or experiment-collected battery life cycle test data of each battery cell 1211.

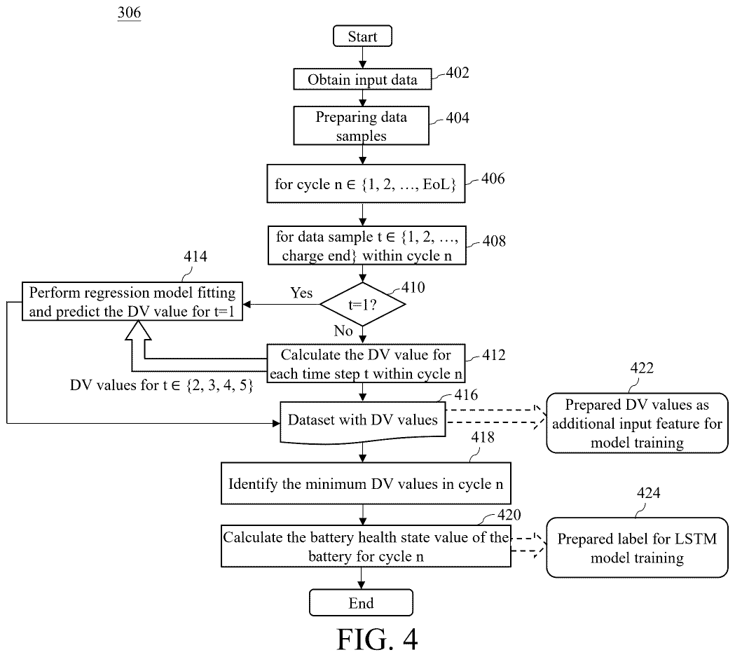

In block 306, differential voltage (DV) calculation is performed on the collected battery data to prepare for the battery health state value estimation for respective charging cycles, and the estimated battery health state values will also serve as data labels for model training (block 314). In some embodiments, the software module 211 may be configured to perform the operation in block 306, the details of which will be described with reference to FIG. 4.

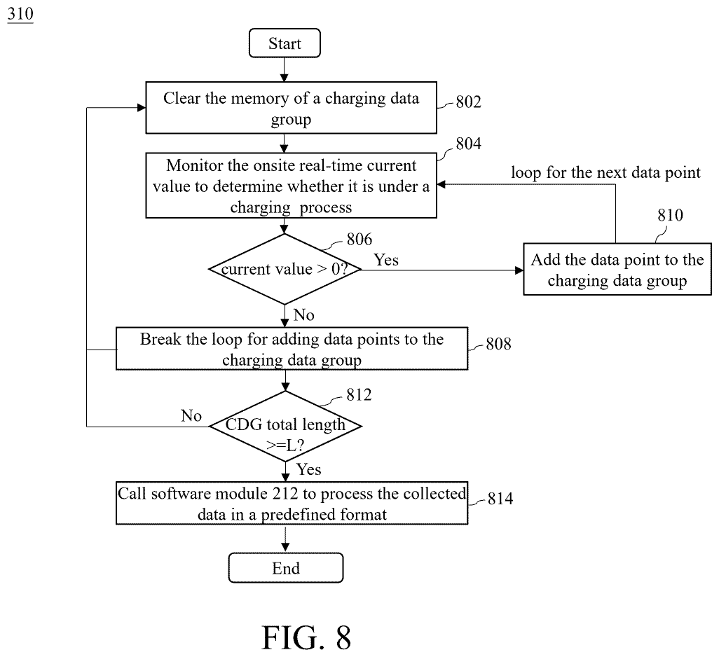

In block 308, deployment of the battery energy storage system 10 starts. In some embodiments, the battery energy storage system 10 may be deployed for home use or shopping malls, but the present disclosure is not limited thereto. Upon successful deployment of the battery energy storage system 10, the battery energy storage device 100 starts to collect onsite battery charging data (e.g., deployment battery data) (block 310), which includes real-time battery charging information of each battery cell 1211 within the deployed battery energy storage device 100. In some embodiments, the software module 215 is configured to perform the operation in block 310, the details of which will be described with reference to FIG. 8.

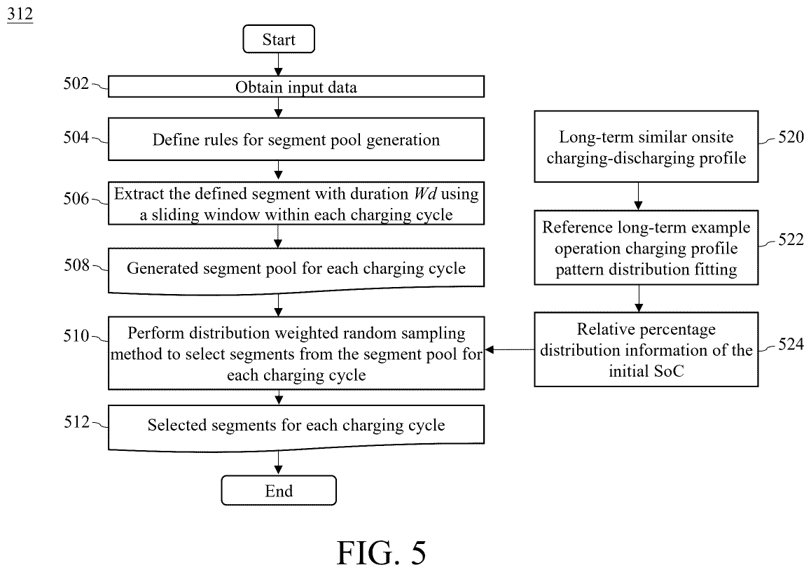

In block 312, customized time series segments (or measurements) are extracted from the collected battery life cycle test data (e.g., from block 304) and collected onsite battery charging data (e.g., from block 310), thereby obtaining prepared charging data segments as an input for model training (block 316) and obtaining collected onsite charging data segments (block 320). It should be noted there may be a very limited amount of existing onsite charging data segment samples (block 318), which can serve as another input data in block 312 for extraction. Additionally, the differential voltages calculated in block 306 may serve as an additional feature inserted to the open-source battery data from which the customized time series segments are extracted in block 312. In some embodiments, the software module 212 is configured to perform the operations in block 312, the details of which will be described with reference to FIG. 5.

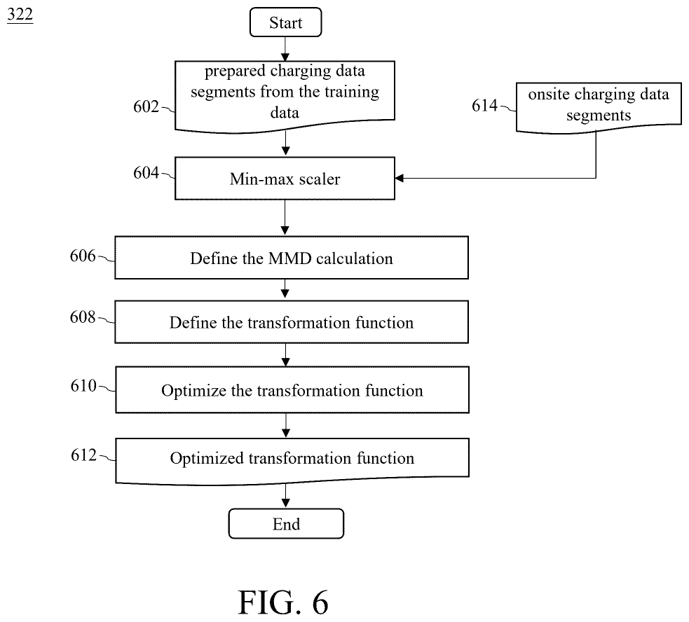

In block 322, a maximum mean discrepancy (MMD) transformation function can be built using the prepared charging data segments in block 316 and the limited onsite charging data segment samples in block 318. In some embodiments, the software module 213 is configured to perform the operation in block 322, the details of which will be described with reference to FIG. 6. Additionally, the onsite charging data segments from block 320 can be input to the optimized MMD transformation function in block 322 to obtain transformed charging data segments.

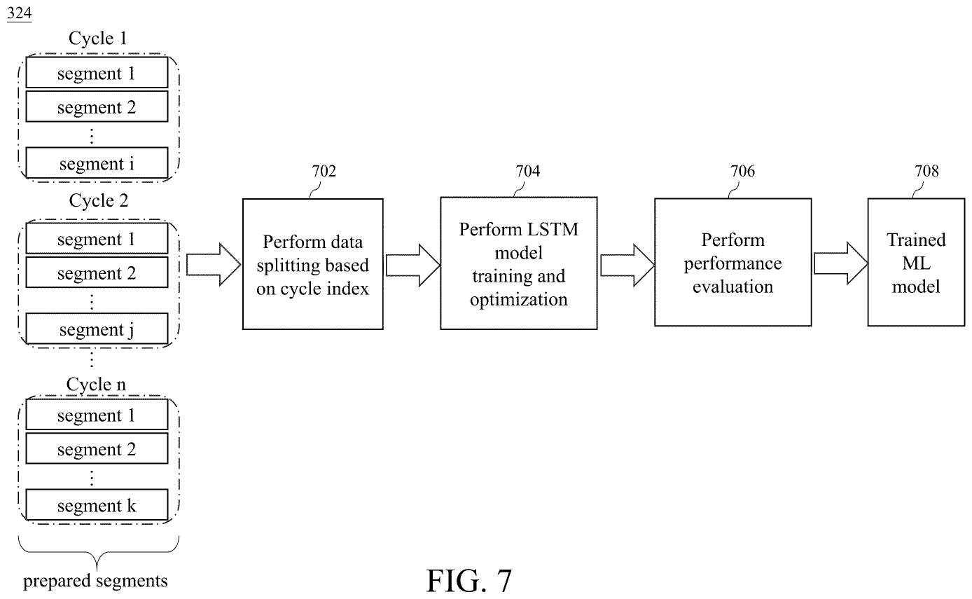

In block 324, model training and optimization is performed. For example, the machine-learning model 217 may be an LSTM model, and the processor 202 may train the machine-learning model 217 using the calculated data labels in block 314 and the prepared charging data segments in block 316, thereby obtaining the trained model (block 328). Additionally, the transformed charging data segments can be input to the trained machine-learning (ML) model in block 328 to generate a predicted battery health state value of a specific battery cell. In some embodiments, the software module 214 is configured to perform the operation in block 324, the details of which will be described with reference to FIG. 7.

In block 330, it is determined whether the predicted battery health state value of the specific battery cell 1211 is within a safe range. When it is determined that the predicted battery health state value is within the safe range, flow 300 ends. When it is determined that the predicted battery health state value is not within the safe range, flow 300 proceeds to block 332, and it indicates that the specific battery cell 1211 within the battery energy storage device 100 may not operate normally. Thus, the processor 202 may report a maintenance request of the battery energy storage device 100 to a central maintenance department for repairing or changing the battery module 121 including the specific battery cell 1211.

Accordingly, the trained machine-learning model (e.g., an LSTM model) is advantageous to provide a highly accurate, data-driven prediction of battery health state by considering different battery degradation stress factors comprehensively based on multiple dimensional time series data. Additionally, the trained machine-learning model can be deployed for a newly developed battery energy storage system even when there are very limited available operation data sample, thus facilitating the cold-start of the machine-learning model.

It should be noted that the predicted battery health state value in FIG. 3A is for a specific battery cell 1211 within the battery energy storage device 100. When the predicted battery health state value of a specific battery cell 1211 is equal to or larger than a predetermined value m, the processor 202 may determine that the specific battery 1211 is in a healthy condition. When the predicted battery health state value of a specific battery cell 1211 is smaller than the predetermined value m, the processor 202 may determine that the specific battery 1211 is in a degraded condition.

In some embodiments, the processor 202 is configured to fit the curve of predicted battery health state values of the specific battery cell 1211 as a cubic polynomial function, and calculate a quadratic derivative of the cubic polynomial function. When the quadratic derivative is zero, the processor 202 may select the battery health state value, which corresponds to the position with its quadratic derivation being zero, as the predetermined value m.

In some embodiments, the processor 202 may determine the health state of a specific battery module 121 using the battery health state values of the battery cells 1211 therein. For example, for the specific battery module 121, if less than a predetermined percentage of battery cells 1211's battery health states are in the degraded condition (e.g., battery health state values are less than the predetermined value m), the processor 202 may determine that the specific battery module 121 can operate normally. The predetermined percentage may be 25%, and it can be adjusted according to users' needs. If more than the predetermined percentage of battery cells 1211's battery health states are in the degraded condition (e.g., battery health state values are less than the predetermined value m), the specific module 121's charging or discharging current I and target full charge capacity Q would be adjusted by a multiplying a dynamic factor R, which can be expressed by the following formula:

$$R = ( 1 - \frac{m - h}{m} * 0.2 ) ,$$

where m is the defined threshold value, and h is the predicted smallest battery cell health state value within a battery module 121. Therefore, the adjusted current I′=I*R, thereby reducing the charging/discharging power stress. Additionally, the adjusted target full charge capacity Q′=Q*R, thereby avoiding the overcharging stress.

FIG. 4 is a flowchart of operations in block 306 in accordance with the embodiment of FIG. 3A. Please refer to FIGS. 3A and 4 simultaneously.

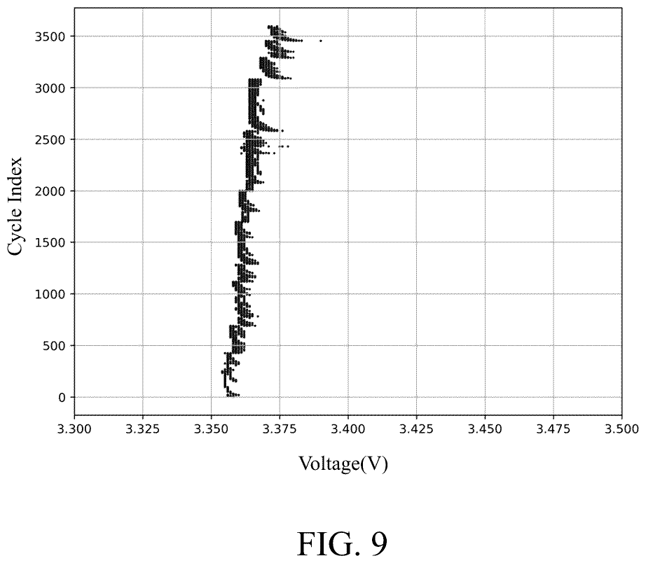

In some embodiments, the software module 211 may be configured to extract the battery health state value (e.g., health state indicator) of each battery module 121 by analyzing the curve features of the differential voltage (DV) values derived from open-source battery data, as depicted in blocks 304 and 306 of FIG. 3A, thereby obtaining data labels for training the machine-learning model 217. In some embodiments, the differential voltage DV is computed based on the variations in voltage V and charge capacity Q of each battery module 121 within the battery energy storage device 100, where the charge capacity Q is calculated as the integral of current over time. Specifically, the open-source battery data records relationships between the differential voltage, voltage, and cycle index (e.g., the number of charging cycles), forming a three-dimensional data space. For clarity, FIG. 9 illustrates the relationship between voltage corresponding to the minimum DV value and the cycle index. As can be seen from FIG. 9, the trend of the voltage corresponding to the minimum DV value tends to increase gradually with the cycle index. As such, the voltage corresponding to the minimum DV value can be used to define the battery health state value within each charging cycle.

In block 402, input data is obtained. In some embodiments, the input data is open-source or experiment-collected battery life cycle covered data, which includes different stages of the battery cells of the same type as the battery cell 1211, such as the new stage, middle life stage, aged stage, and end of life (EoL) stage.

In block 404, the data samples are prepared. In some embodiments, several operations may be performed in block 404, including performing a data cleaning process on the data samples, organizing the data samples according to the cycle index, and extracting the charge period data for each test cycle.

In some embodiments, the blocks 406 to 424 may define the operations for each data sample (e.g., voltage) within each charging cycle. For example, in block 406, the cycle index n may be from 1 to EoL, where EoL is a positive integer. In some embodiments, the value of EoL may be approximately several thousands. Additionally, in block 408, the timestamp points of the data samples (e.g., voltages) are indexed from 1 to “CE” within cycle n, where “CE” refers to the “charge end” (e.g., SoC=100%).

In block 410, it is determined whether the index of the data sample is 1. When it is determined that the index of the data sample is 1 (e.g., the first data sample), the flow proceeds to block 414. When it is determined that the index of the data sample is not 1, the flow proceeds to block 412.

In block 412, the DV value is calculated for each timestamp point t within cycle n. In some embodiments, the DV value at timestamp point 2 (e.g., t=2) can be calculated using the data samples (e.g., voltages) at timestamp points 1 and 2, and the DV value at time step 3 (e.g., t=3) can be calculated using the data samples (e.g., voltages) at timestamp points 2 and 3, and so forth. For purposes of description, it is assumed that the charged capacity Q of a battery monotonically increases during a charging process of the battery. The differential voltage (DV) can be expressed using formula (1) as follows.

$${D V}_{n , t} = \frac{{d V}_{n , t}}{{dQ}_{n , t}} = \frac{{V}_{n , t} - {V}_{n , t - 1}}{{Q}_{n , t} - {Q}_{n , t - 1}} \qquad ( 1 )$$

In formula (1), V denotes the measured voltage of the battery; Q denotes the charged capacity of the battery; n denotes the cycle number; and t denotes the time step of the data measurement.

It should be noted that the DV value at timestamp point 1 (e.g., t=1) cannot be calculated in a similar manner since the data sample prior to timestamp point 1 is absent. Accordingly, in block 414, the DV values at timestamp points 2 to 5 can be used as reference information to perform regression model fitting to predict the DV value for timestamp point 1. For example, the first DV value of each charging cycle will be fitted by a local linear regression method by considering the following four calculated DV values at timestamp points 2 to 5. The loop from blocks 406 to 420 can be performed repeatedly until the data samples within all cycles in the open-source battery data have been processed, thereby obtaining the calculated data labels for model training (block 416). Additionally, the dataset with calculated DV values in block 416 may serve as the prepared DV values as an additional input feature for model training (e.g., for block 312 in FIG. 3A).

In block 418, the minimum DV value in cycle n is identified, and its corresponding voltage is noted. In some embodiments, when the DV value decreases to a minima in cycle n, the voltage corresponding to the DV minima can be obtained and denoted as V_{min,n}. When multiple minimum DV points occur in the same charging cycle, the average of the voltages corresponding to these minimum DV points serves as the voltage V_{min,n} corresponding to the DV minima.

In block 420, the health state of the battery for cycle n is calculated. In some embodiments, for purposes of description, it is assumed that the health state of the battery within a cycle is constant, and the data-covered charging cycles are from new stage to the EoL stage of the battery. For cycle n, the health state of the battery at cycle n (e.g., HealthStateₙ) can be expressed using formula (2) as follows.

$${HealthState}_{n} = 1 - \frac{{V}_{min , n} - {V}_{min , new}}{{V}_{min , EoL} - {V}_{min , new}} \qquad ( 2 )$$

In formula (2), V_{min,n} denotes the voltage corresponding to the minimum DV value for cycle n; V_{min,new} denotes the voltage corresponding to an initial minimum DV value when the battery is in a new stage (e.g., corresponding to an initial charging cycle of the battery); and V_{min,EOL} denotes the voltage corresponding to the minimum DV value when the battery cell is in an EoL stage (e.g., corresponding to an EoL charging cycle of the battery).

FIG. 5 is a flowchart of operations in block 312 in accordance with the embodiment of FIG. 3A. Please refer to FIGS. 3A and 5 simultaneously.

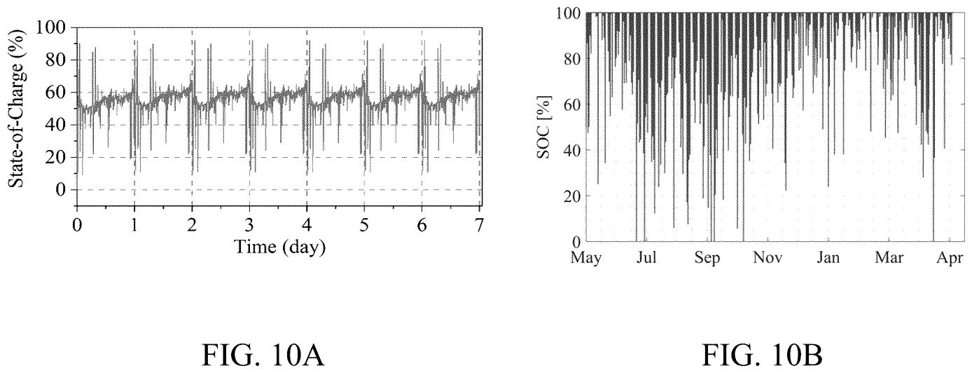

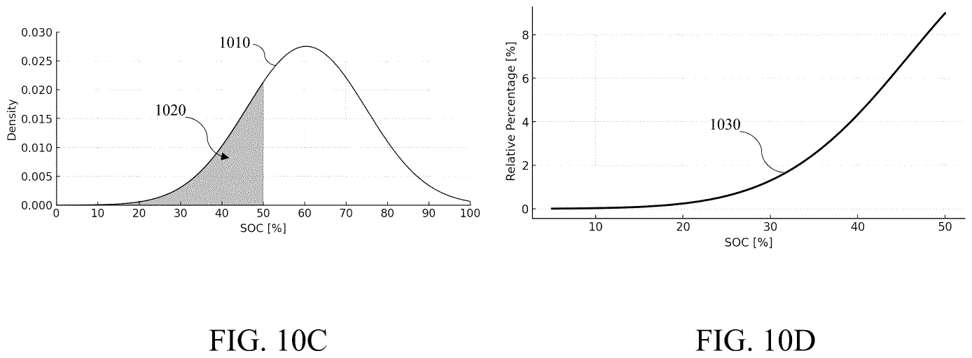

In some embodiments, the onsite battery charging data of the deployed battery energy storage system 10 may exhibit variability. For clarity, examples of a short-term case (e.g., for one week) and a long-term case (e.g., for one year) of the onsite battery charging data are illustrated in FIGS. 10A and 10B, respectively. Specifically, the randomness of the onsite charging cycle data arises from varying initial states of charge (SoC) and differing charging periods (or the charging end SoCs).

The software module 212 is configured to perform the operations in block 312 in FIG. 3A, which aim to take the time series segments as inputs for training the machine-learning model 217 (e.g., LSTM model). Additionally, an LSTM model needs the input battery charging data to maintain a fixed length (e.g., fixed time length) and a fixed dimension, and operations in block 312 can effectively extract time series segments with the fixed length from the open-source battery data and the onsite charging data.

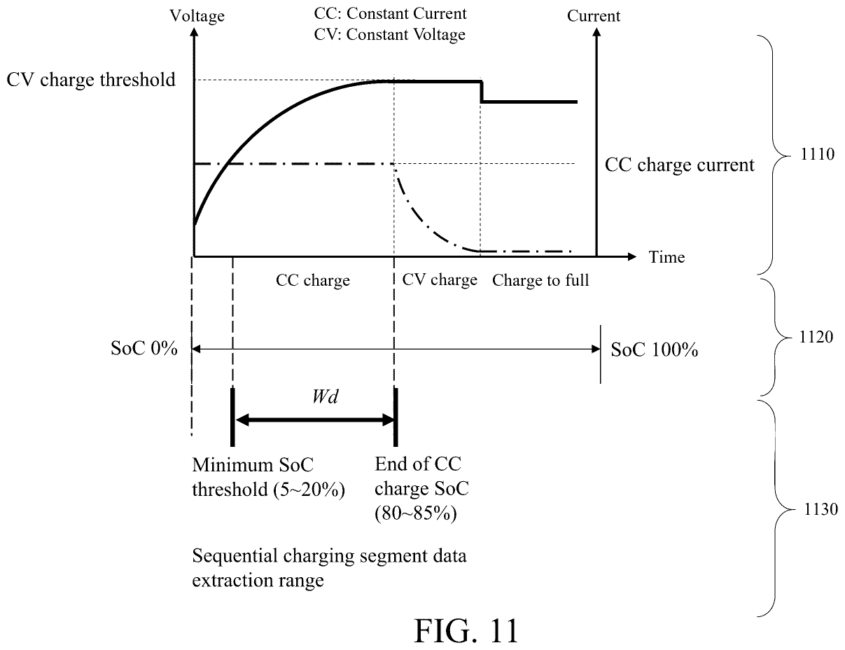

In some embodiments, a schematic diagram of a battery charging profile of a battery (e.g., a lithium-ion battery, such as battery module 121 or battery cell 1211) is shown by the first portion 1110 in FIG. 11. The variations of the SoC value over time during the charging process of the battery is shown by the second portion 1120 in FIG. 11. The charging data extraction time window range is illustrated by the third portion 1130 in FIG. 11. For example, constant-current (CC) charging and constant-voltage (CV) charging techniques can be employed during the charging process of the battery. When the SoC of the battery is below a particular SoC (e.g., 80 to 85%), the constant-current charging technique is applied. When the SoC of the battery reaches the particular SoC, the constant-voltage technique is used until the SoC of the battery reaches 100%.

Specifically, the open-source battery data may have charging data of the battery with an SoC ranging from 0% to 100% or from 20% to 80%. Additionally, the time window size (e.g., duration or length) Wd for data extraction can be appropriately defined based on specific requirements. For example, when time series segments with a fixed length (or fixed duration) are to be extracted from source charging data to serve as the input for the machine-learning model 217, and such source charging data with the same length feature is derived from the collected onsite charging data. For example, when the source charging data has a relatively short charging period, it is challenging to effectively extract time series segments from the source charging data using a larger time window size Wd. Therefore, it is preferable to define a narrower time window size Wd to increase the probability of extracting time series segments of a fixed length from the source charging data. Conversely, when it is needed to cover more charging pattern details to improve the performance of the trained machine-learning model 217, a larger time window size Wd is preferred to be defined.

In some embodiments, for clarity, charge time durations under different conditions of an LPF battery using the constant-current technique are illustrated in Table 1 as follows.

TABLE 1

| | 1 C rate_CC phase | 0.5 C rate_CC phase |
|---|---|---|
| initial SoC (%) | duration (min) | duration (min) |
| 20 | 52 | 104 |
| 30 | 42 | 84 |
| 40 | 27 | 54 |
| 50 | 21 | 42 |

In the embodiment of Table 1, the CC charging procedure ends when the SoC of the LPF battery reaches approximately 85%. For example, if the initial SoC is 20%, it may require approximately 52 minutes using the constant-current charging technique with a charge rate of 1 C. Similarly, if the initial SoC is 30%, it may require approximately 42 minutes using the constant-current charging technique with a charge rate of 1 C, and so forth. Additionally, given that the initial SoC is 20%, it may take approximately 104 minutes using the constant-current charging technique with a charge rate of 0.5 C. Given that the initial SoC is 30%, it may take approximately 84 minutes using the constant-current charging technique with a charge rate of 0.5 C, and so forth. It should be noted that charging at a charge rate of 1 C means that the battery is charged from 0% to 100% SoC in one hour (60 minutes), while charging at a charge rate of 0.5 C means that the battery is charged from 0% to 100% SoC in two hours (120 minutes).

In some embodiments, the time window size Wd used in block 312 can be set between 30 and 50 minutes, such as set to 40 minutes for training the machine-learning model 217. Accordingly, for a charge rate of 1 C, the initial SoC of approximately 30% and below would generate time series segments with lengths long enough. For a charge rate of 0.5 C, the initial SoC of approximately 50% and below would generate time series segments with lengths long enough. In some embodiments, when the initial SoC is too high, it may cause the length of the corresponding collected time series segment to be shorter than 40 minutes. This collected time series segment will not be used for predicting the battery health state value of the deployed battery energy storage system 10. Accordingly, the trained machine-learning model 217 provides a discrete prediction capability which is determined by the onsite operation patterns.

Attention now is directed back to FIG. 5. In block 502, the input data is obtained. For example, the input data may include a variety of characteristics of the open-source battery data, such as the voltage, current, charge capacity, temperature, and calculated DV value for every charging cycle of the battery.

In block 504, rules for segment pool generation are defined. In some embodiments, the rules may include: 1) the initial SoC upon start of charging ranges from 5% to 50%; 2) the charging end SoC is 85%; and 3) the segment length is 40 minutes. The details about these rules can be referred to the aforementioned embodiment.

In block 506, the defined segment with duration Wd is extracted using a sliding window within each charging cycle. In some embodiments, the duration (e.g., time window size) Wd is approximately 40 minutes, but the present disclosure is not limited thereto. Additionally, a step size may be 1 time interval (e.g., 1 minute) of the open-source battery data and the onsite charging data. Accordingly, a plurality of time series segments can be obtained for each charging cycle, forming a segment pool for each charging cycle (block 508). It should be noted that the duration Wd may differ for various types of lithium-ion batteries, such as NMC batteries and LCO batteries, due to their specific technological properties.

In block 510, a distribution weighted random sampling method is performed to select segments from the segment pool for each charging cycle. In some embodiments, when a charging record data sample has a length longer than 40 minutes, a distribution weighted sampling method is performed to extract multiple time series segments with a fixed length, and a segment pool including a plurality of time series segments will be generated for this charging cycle. In some embodiments, the maximum total number of selected segments for each charging cycle is fixed, such as 5. Subsequently, an average among the multiple predictions is calculated as an output. Additionally, the segment pool for each charging cycle can be collectively regarded as an overall segment pool for training the machine-learning model 217.

In some embodiments, for brevity, a long-term similar onsite battery charging profile (block 520), which is associated with another battery energy storage device similar to the battery energy storage device 100, is obtained. A reference long-term example (block 522), which including distribution fitting of the initial SoC values shown in FIG. 10C, can be derived from the long-term similar onsite battery charging profile. The curve 1010 shown in FIG. 10C can be expressed using formula (3) as follows.

$$f ( x ) = \frac{1}{14.5 \sqrt{2 π}} \text{?} \qquad ( 3 )$$

$$\text{?} \text{indicates text missing or illegible when filed}$$

In formula (3), x denotes the SoC value, and ƒ(x) denotes the distribution density function of a variable x. It should be noted that the distribution density function ƒ(x) may vary depending on the characteristics, such as varying usage behaviors, seasonality, and products, of the selected long-term similar onsite battery charging profile in block 520. In this example, the shaded area 1020 in FIG. 10C, which includes SoC values ranging from 5% to 50%, may occupy 23.7% area of the overall integral area of the function ƒ(x). This indicates that 23.7% of the whole service charging records in FIG. 10C can be utilized for battery health prediction. Additionally, there is a chance to obtain suitable operation data from the reference long-term example in block 522 and perform battery health prediction approximately every 4.5 days. Furthermore, the shaded area 1020 in FIG. 10C can be reorganized using the relative percentages of the initial SoC values ranging from 5% to 50% within the shaded area 1020 in FIG. 10C, thereby obtaining curve 1030 shown in FIG. 10D, which represent the relative percentage distribution of the initial SoC (block 524). Accordingly, the processor 202 may perform the distribution weighted random sampling method to select segments from the segment pool for each charging cycle by randomly select a plurality of segments (e.g., at most 5 segments for one cycle) from the segment pool using the relative percentage of the initial SoC value as corresponding weight information.

FIG. 6 is a flowchart of operations in block 322 in accordance with the embodiment of FIG. 3A. Please refer to FIGS. 3A and 6 simultaneously.

In some embodiments, the software module 213 may be configured to establish a maximum mean discrepancy (MMD) transformation model using the prepared charging data segments (e.g., training data from block 316) and the collected onsite charging data segments (e.g., onsite data from block 320), thereby aligning the onsite charging data segments with the prepared charging data segments before deploying the trained machine-learning model 328. It should be noted that that MMD method may be used as a preprocessing method, and it can work well using small, unbalanced datasets. Additionally, the training data for the machine-learning model 217 may be the prepared charging data segments from open sources or experiments, which may include hundreds or thousands of segments. The onsite data may refer to the limited amount of onsite-collected operation data, which includes at least one typical cycle of a battery charging record. Additionally, each of the prepared charging data segments include battery-cell level characteristics, such as the voltage, current, capacity, temperature, and differential voltage.

In block 604, a min-max scaler is fitted using the prepared charging data segments (block 602). Blocks 602 and 614 may correspond to blocks 316 and 318 in FIG. 3A, respectively. In some embodiments, the min-max scaler is a data preprocessing technique used to normalize the range of independent variables or features of data. It scales the data to a fixed range, typically [0, 1], by transforming each feature individually. For brevity, it is assumed the range of scaled featured value is [0, 1], and the min-max scaler can be expressed using formula (4) as follows.

$${X}_{scaled} = \frac{X - {X}_{min}}{{X}_{max} - {X}_{min}} \qquad ( 4 )$$

In formula (4), X_{scaled} denotes the scaled feature value; X denotes the original feature value; Xₘᵢₙ and Xₘₐₓ represent the minimum and maximum values of the feature in the dataset. This technique is useful in machine learning algorithms that are sensitive to the scale of data, such as k-nearest neighbors and neural networks, as it ensures that all features contribute equally to the result. The onsite charging data segments (e.g., block 614 in FIG. 6 or block 320 in FIG. 3A) are input to the min-max scaler in block 604 to obtain processed onsite charging data segments, which are sent to the MMD calculation in block 606 along with the prepared charging data segments in block 602. It should be noted that once the min-max scaler in block 604 is built, it can be kept for use by block 322 during the subsequent inference (or deployment) procedure shown in FIG. 3C. This allows the collected onsite charging data segments in block 320 to be processed by the min-max scaler in block 604. The processed data segments are then input to the MMD transformation function in block 322 to obtain the transformed charging data segments in block 326.

In block 606, maximum mean discrepancy (MMD) is calculated. In some embodiments, the maximum mean discrepancy (MMD) transformation is a technique used in statistical analysis and machine learning to measure the difference between two probability distributions. It is particularly useful in scenarios like domain adaptation, where the goal is to align the distributions of data from different domains. In some embodiments, the discrepancy between distributions of two sequential data sets can be measured using a radial basis function (RBF) kernel based on formula (5) as follows.

$$K ( {X}_{si}^{seg} , {X}_{sj}^{seg} ) = exp ( - γ {\sum }_{n = 1}^{N} {‖ {X}_{si}^{( n )} - {X}_{sj}^{( n )} ‖}^{2} ) \qquad ( 5 )$$

In formula (5),

$${X}_{si}^{seg} and {X}_{sj}^{seg}$$

are the segments representing the i^{th} and j^{th} cycle, respectively;

$$γ = \frac{1}{2 {σ}^{2}} ,$$

σ is based on the pairwise distance between segments of training data (e.g., the prepared charging data segments in block 602) and onsite data (e.g., onsite charging data segments processed by the min-max scaler in block 604); and N represents the total number of steps in a segment (according to the segment extraction length and time interval).

In some embodiments, the MMD calculation in block 606 may quantify how similar the onsite data segments are to the training data segments. The MMD calculation can be expressed using formula (6) as follows.

$${MMD}^{2} ( {X}_{t}^{seg} , {X}_{o}^{seg} ) = \frac{1}{{n}_{o}^{2}} {\sum }_{i = 1}^{no} {\sum }_{j = 1}^{no} K ( {X}_{oi}^{seg} , {X}_{oj}^{seg} ) + \frac{1}{\text{?}} {\sum }_{i = 1}^{nt} {\sum }_{j = 1}^{nt} K ( {X}_{ti}^{seg} , {X}_{tj}^{seg} ) - \frac{2}{\text{?} {n}_{t}} \qquad ( 6 )$$

$${\sum }_{i = 1}^{no} {\sum }_{j = 1}^{nt} K ( {X}_{oi}^{seg} , {X}_{tj}^{seg} )$$

$$\text{?} \text{indicates text missing or illegible when filed}$$

In formula (6),

$${X}_{t}^{seg} and {X}_{o}^{seg}$$

represent the sets of training and onsite data segments, respectively; no and nt represent the numbers of samples within the training data segments and onsite data segments, respectively.

In block 608, the transformation function is defined. In some embodiments, the transformation function can be expressed using formula (7) as follows.

$$T ( {X}_{o}^{seg} ) = W \cdot {X}_{o}^{seg} + b \qquad ( 7 )$$

In formula (7),

$${X}_{o}^{seg}$$

represents the sets of training data segments; W denotes the weighting matrix; and b denotes the offset matrix.

In block 610, the transformation function is optimized. In some embodiments, the MMD distance between the onsite data segments and training data segments can be minimized using formula (8) as follows.

$${min}_{W , b} {MMD}^{2} ( T ( {X}_{o}^{seg} ) , {X}_{t}^{seg} ) \qquad ( 8 )$$

Specifically, the transformation function T can be achieved by adjusting the variables W and b, so that when the value of MMD's square comes to the minimal state, the optimization process ends, and the optimized transformation function T (block 612) is found.

FIG. 7 is a flowchart of operations in block 324 in accordance with the embodiment of FIG. 3A. Please refer to FIGS. 3A and 7 simultaneously.

In some embodiments, the software module 214 is configured to perform the operations in block 324 in FIG. 3A, such as performing model training and optimization on the machine-learning model 217, thereby obtaining the trained machine-learning (ML) model 328. It should be noted that the data labels (e.g., health state values) obtained from block 306 can be used in conjunction with the prepared charging data segments obtained from block 312 for training the machine-learning model 217. The prepared charging data segments may include respective segments for each charging cycle, such as segments 1 to i for charging cycle 1, segments 1 to j for charging cycle 2, and segments 1 to k for charging cycle n.

In block 702, data splitting is performed based on cycle index. For brevity, the respective segments in each charging cycle can be split into one of a first dataset, a second dataset, and a third dataset, which can be regarded as a training dataset, a validation dataset, and a test dataset, respectively. This indicates that the segments within the same cycle are split to the same dataset, which could be the training dataset, validation dataset, or test dataset. In some embodiments, the percentages for splitting the respective cycles to the first dataset, the second dataset, and the third dataset may be 50%, 20%, and 30%, respectively, but the present disclosure is not limited thereto.

In block 704, the LSTM model training and optimization are performed. In some embodiments, the machine-learning model 217 is initially trained using the training dataset. Subsequently, the validation dataset can be input to the trained machine-learning model 217 to provide an unbiased evaluation of a model fit on the training dataset while tuning the machine-learning model 217's hyper-parameters, such as the number of LSTM layer, the number of neurons, learning rate, number of epochs, batch size, optimizer, tuning method, loss function etc. For example, the validation dataset can be used for regularization by early stopping, such as stopping training when the error on the validation data set increases, as this is a sign of over-fitting to the training data set. Finally, the test dataset can be input to the trained machine-learning model 217 to provide an unbiased evaluation of a final model fit on the training dataset.

In block 706, performance evaluation is performed. For example, the performance of the trained machine-learning model 217 can be evaluated using a plurality of metrics, such as the mean absolute error (MAE), mean squared error (MSE), root mean squared error (RMSE), and mean absolute percentage error (MAPE) between the predicted health state value and the actual heal state value. When the evaluated performance of the trained machine-learning model 217 meets the requirements, a final version of the trained machine-learning model is obtained (block 708).

FIG. 8 is a flowchart of operations in block 310 in accordance with the embodiment of FIG. 3A. Please refer to FIGS. 3A and 8 simultaneously.

In some embodiments, the software module 215 is configured to perform the operations in block 310 in FIG. 3A, such as repeatedly monitoring the real-time onsite battery information to obtain qualified onsite charging data.

In block 802, the memory of a charging data group is cleared. In some embodiments, the memory (e.g., memory 204 shown in FIG. 2) is cleared for initialization purposes.

In block 804, the onsite real-time current value is monitored to determine whether it is in a charging process. In some embodiments, the software module 215 seeks to obtain qualified onsite charging data with a predefined length from the deployed battery energy storage system 10. Accordingly, the current value of a specific battery cell 1211 can be monitored to determine whether the deployed battery energy storage system 10 is in a charging process. For example, when the current value is a positive value (e.g., >0), it indicates that the deployed battery energy storage system 10 is under a charging process. When the current value is 0, it indicates that the specific battery cell 1211 in the deployed battery energy storage system 10 is neither charging or discharging, nor is it connected to a load. When the current value is a negative value (e.g., <0), it indicates that the specific battery cell 1211 in the deployed battery energy storage system 10 is discharging to a load.

In block 806, it is determined whether the current value is greater than 0. When it is determined that the current value is greater than 0, it indicates that the specific battery cell 1211 in the deployed battery energy storage system 10 is in a charging process, and thus the data point can be added to the charging data group (block 810). The loop between blocks 804, 806, and 810 can be repeatedly performed when the deployed battery energy storage system 10 is in the charging process, and the data length of the charging data group increases as the charging process continues. In some embodiments, the data points with the charging data group may be recorded every predetermined time interval (e.g., 1 minute). When it is determined that the current value is greater than 0, it indicates that the deployed battery energy storage system 10 is not in a charging process, such as when the charging process has been stopped. Thus, the loop for adding data points to the charging data group is broken (block 808).

In block 812, it is determined whether the total length of the charging data group (CDG) is equal to or longer than a predetermined time L (e.g., 40 minutes). When it is determined that the total length of the charging data group (CDG) is equal to or longer than the predetermined time L, it indicates that the charging data group can be used to extract onsite charging data segments by calling the software module 212 to process the collected data in a predefined format, such as onsite charging data segments each with a total length of approximately 40 minutes. When it is determined that the total length of the charging data group (CDG) is shorter than the predetermined time L, it indicates that the total length of the present charging data group is not long enough, which is not qualified as an onsite charging data segment.

In view of the above, a battery energy storage system and a method for predicting a battery health state value thereof are provided, which are capable of accurately predicting the battery health of a battery energy storage system using a machine-learning model trained using time series data of multiple parameters. Additionally, the trained machine-learning model can be deployed for a newly developed battery energy storage system even when there are very limited available operation data sample, thus facilitating the cold-start of the machine-learning model.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A computer system, comprising:
a processor; and
a memory having computer-executable instructions stored thereupon which, when executed by the processor, cause the computer system to:
collect a plurality of time series measurements, which comprise voltage measurements and charge capacity measurements, sampled from a reference battery module over a plurality of charging cycles;
calculate a plurality of differential voltage (DV) values based on the voltage measurements and the charge capacity measurements corresponding to the each of the plurality of charging cycles;
identify a plurality of minimum DV values each corresponding to a respective charging cycle of the plurality of charging cycles;
calculate a plurality of battery health state values corresponding to the plurality of charging cycles based on the plurality of minimum DV values;
extract a segment pool, which comprises a plurality of data segments, from the time series measurements over a plurality of constant current charging phases corresponding to the plurality of charging cycles; and
train a machine-learning model with the segment pool and corresponding ones of the plurality of battery health state values.

2. The computer system as claimed in claim 1, wherein the plurality of minimum DV values comprise of an initial minimum DV value corresponding to an initial charging cycle of the reference battery module, an end minimum DV value corresponding to an end-of-life (EoL) charging cycle of the reference battery module, and an N-th minimum DV value corresponding to an N-th charging cycle.

3. The computer system as claimed in claim 2, wherein the battery health state value is labeled with a new battery health state value for a new battery condition, and is labeled with an EoL battery health state value for an EoL battery condition.

4. The computer system as claimed in claim 1, wherein the plurality of time series measurements further comprise of current measurements, charge capacity measurements, and temperature measurements.

5. The computer system as claimed in claim 1, wherein the memory having further computer-executable instructions stored thereupon which, when executed by the processor, cause the computer system to:
extract the plurality of first data segments based on a predefined moving window with a fixed time length and a fixed dimension.

6. The computer system as claimed in claim 2, wherein the memory having further computer-executable instructions stored thereupon which, when executed by the processor, cause the computer system to:
calculate the DV values of a plurality timestamp points within the respective one of the charging cycles;
extract the plurality of minimum DV values from the plurality of DV values within the respective one of the charging cycles; and
obtain voltages corresponding to the plurality of minimum DV values.

7. The computer system as claimed in claim 6, wherein the memory having further computer-executable instructions stored thereupon which, when executed by the processor, cause the computer system to:
calculate the DV values corresponding to second to fifth timestamp points within the respective one of the charging cycles; and
perform regression model fitting, using the DV values of the second to fifth timestamp points, to predict the DV value corresponding to a first time interval within the respective one of the charging cycles.

8. The computer system as claimed in claim 6, wherein the memory having further computer-executable instructions stored thereupon which, when executed by the processor, cause the computer system to:
calculate a respective one of the plurality of first battery health state values corresponding to the first N-th charging cycle based on the initial first minimum DV value, the end first minimum DV value, and the N-th first minimum DV value.

9. The computer system as claimed in claim 1, wherein the memory having further computer-executable instructions stored thereupon which, when executed by the processor, cause the computer system to:
identify initial state-of-charge (SoC) values and time lengths of the plurality of first constant current charging phases; and
apply a distribution weighted sampling process on the plurality of first constant current charging phases to extract the plurality of first data segments based on the initial SoC values and the time lengths of the plurality of first constant current charging phases.

10. The computer system as claimed in claim 9, wherein the memory having further computer-executable instructions stored thereupon which, when executed by the processor, cause the computer system to:
obtain a long-term battery charging profile of a battery module similar to the target battery module;
build a density distribution function with respect to the initial SoC values; and
reorganize the density distribution function to a relative percentage distribution function of the initial SoC values within a predetermined range.

11. The computer system as claimed in claim 10, wherein predetermined range of the initial SoC values is from 5% to 50%.

12. The computer system as claimed in claim 10, wherein the time lengths are between 30 and 50 minutes.

13. The computer system as claimed in claim 1, wherein the machine-learning model is a long short-term memory (LSTM) model.

14. The computer system as claimed in claim 1, wherein the memory having further computer-executable instructions stored thereupon which, when executed by the processor, cause the computer system to:
split the plurality of data segments within the segment pool corresponding to a respective one of the plurality of charging cycles into one of a first dataset, a second dataset, and a third dataset;
train the machine-learning model using the first dataset corresponding to the respective one of the plurality of charging cycles;
validate the trained machine-learning model using the second dataset corresponding to the respective one of the plurality of charging cycles; and
test the trained machine-learning model using the third dataset corresponding to the respective one of the plurality of charging cycles.

15. The computer system as claimed in claim 14, wherein the memory having further computer-executable instructions stored thereupon which, when executed by the processor, cause the computer system to:
adjust one or more hyper-parameters of the machine-learning model during training of the machine-learning model.

16. An apparatus for predicting a battery health state value of a target battery module having one or more electrochemical battery cells, the apparatus comprising:
a processor; and
a memory, having computer-executable instructions stored thereupon which, when executed by the processor, cause the apparatus to:
obtain a machine-learning model, which has been trained with a plurality of first data segments and a plurality of first battery health state values corresponding to the plurality of first data segments associated with a reference battery module;
collect battery charging data of the target battery module over one or more charging cycles of the target battery module;
extract a second data segment from the battery charging data;
transform the second data segment to align with the plurality of first data segments; and
input the transformed second data segment to the machine-learning model to predict a battery health state value of the target battery module.

17. The apparatus as claimed in claim 16, wherein the memory has further computer-executable instructions stored thereupon which, when executed by the processor, cause the apparatus to:
perform data preprocessing to normalize the plurality of first data segments and one or more third data segments of a battery module similar to the target battery module;
calculate maximum mean discrepancy (MMD) between the normalized first data segments and the normalized one or more third data segments to build a transformation function for transforming the second data segment; and
optimize the transformation function with a minimized MMD distance between the plurality of first data segments and the one or more third data segments.

18. The apparatus as claimed in claim 16, wherein the battery charging data comprises voltage measurements, current measurements, charge capacity measurements, and temperature measurements.

19. The apparatus as claimed in claim 16, wherein the memory has further computer-executable instructions stored thereupon which, when executed by the processor, cause the computer system to:
add data points to a charging data group to serve as the battery charging data in response to the target battery module being in a charging process; and
stop adding the data points to the charging data group in response to the target battery module not being the charging process.

20. The apparatus as claimed in claim 19, wherein the memory has further computer-executable instructions stored thereupon which, when executed by the processor, cause the computer system to:
extract the second data segment from the battery charging data in response to a duration of a constant-current charging phase of the target battery module being longer than a predefined time length.
